(19) United States
(12) Patent Application Publication
(10) Pub. No.: US 2026/0119757 A1
(43) Pub. Date: Apr. 30, 2026

(54) Simulation Method for Characterizing Temporal and Spatial Evolution of Groundwater Level

(71) Applicant: Capital Normal University, Beijing (CN)

(72) Inventors: Huili Gong, Beijing (CN); Lin Guo, Beijing (CN); Zijian Wang, Beijing (CN); Lin Zhu, Beijing (CN); Xiaojuan Li, Beijing (CN); Xueqi Zhu, Beijing (CN); Beibei Chen, Beijing (CN); Che Wang, Beijing (CN); Chaofan Zhou, Beijing (CN); Mingliang Gao, Beijing (CN); Bo Gao, Beijing (CN); Jinyan Tian, Beijing (CN)

(21) Appl. No.: 18/950,153

(22) Filed: Nov. 17, 2024

(30) Foreign Application Priority Data
Oct. 31, 2024 (CN) 2024115366781

(51) Int. Cl. G06F 30/28

(52) U.S. Cl. CPC G06F 30/28

(57) ABSTRACT

A simulation method for characterizing the spatiotemporal changes of groundwater levels, which belongs to the technical field of computer machine learning; includes the steps of: obtaining long-term groundwater level data based on long-term groundwater monitoring wells; superimposing multiple hydrogeological parameter information based on groundwater level data; and constructing a regional neural network model with physical mechanism by using a two-dimensional groundwater seepage equation serving as a physical mechanism, thereby simulating the temporal and spatial evolution of regional groundwater levels. The present invention can strengthen the rational use of groundwater resources, implement scientific and effective supervision, and provide a scientific basis for protecting regional groundwater safety and promoting the sustainable development of groundwater resources.

### CROSS REFERENCE OF RELATED APPLICATION

This is a non-provisional application that claims priority to Chinese application number 2024115366781, filing date Oct. 31, 2024, the entire contents is expressly incorporated herein by reference.

### BACKGROUND OF THE PRESENT INVENTION

### Field of Invention

The present invention relates to the field of groundwater simulation technology, and in particular to a new simulation method for characterizing the temporal and spatial evolution of groundwater level.

### Description of Related Arts

Groundwater, which is one of the most important freshwater resources on Earth, not only affects the ecological environment, but also controls the development of social economy. Especially in areas lacking surface water resources, groundwater is often the only reliable water source. Especially in areas lacking surface water resources, groundwater is often the only reliable water source. Globally, more than one-third of the water used by humans comes from groundwater. However, due to factors such as human activities and climate change, the shortage of groundwater resources is becoming increasingly serious, causing many geological environmental problems such as land subsidence, groundwater pollution and ecosystem degradation. In order to effectively manage and protect groundwater resources, simulation and prediction of groundwater is imminent.

Traditional groundwater simulation methods require explicit discretization equations and building networks based on the geometry and boundary conditions of the problem. For complex geometries or multi-physics coupling problems, modeling and solving can be very complex and time-consuming. Traditional groundwater simulation methods are mostly based on control equations, so they have obvious limitations in dealing with nonlinear problems. Compared with traditional numerical simulation methods, machine learning and deep learning algorithms have obvious advantages in solving nonlinear problems and improving computational efficiency. However, these methods are all data-driven, and the models lack physical constraints, which makes it difficult to explain the internal mechanisms of the models and the reliability of the model results is questionable. In order to solve the above problems, the present invention provides a new simulation method for characterizing the temporal and spatial evolution of groundwater level.

### SUMMARY OF THE PRESENT INVENTION

In order to obtain information on groundwater changes over time, and describe the rules of evolution quantitatively, the present invention provides a new simulation method for characterizing the temporal and spatial evolution of groundwater level for efficient groundwater level simulation.

Accordingly, in one aspect of the present invention, the present invention adopts the following technical solutions:

A simulation method to characterize the spatiotemporal change of groundwater level comprises the steps of:

S1: obtaining monthly precipitation data covering a study area through long-term satellite remote sensing precipitation product; obtaining monthly groundwater level data through long-term groundwater monitoring wells within the study area;
S2: obtaining basic hydrogeological data within the study area, combining the basic hydrogeological data with a groundwater control equation, and constructing a two-dimensional groundwater seepage equation for the study area;
S3: creating a deep learning neural network model integrating physical knowledge, namely the PINNs model, based on the two-dimensional groundwater seepage equation of the study area combined with a neural network model;
S4: training the deep learning neural network model integrating physical knowledge—the PINNs model by using the precipitation data and groundwater level data obtained in step S1, thereby obtaining a data error term between network output and the training data;
S5: substituting the network output results obtained from the model in step S4 into a physical equation, solving the physical equation through automatic differentiation, and obtaining a physical residual term;
S6: superimposing the data error term obtained from step S4 with the physical residual term obtained by step S5 to obtain an overall loss of the PINNs model, then processing back-propagation to propagate the overall loss of the PINNs model back to the neural network model, thereby learning is performed through model iteration processing to achieve accurate simulation of groundwater level.

Preferably, when obtaining the monthly precipitation data covering the study area through the long-term satellite remote sensing precipitation product, a geoscientific related software is employed for data processing, wherein the geoscientific related software is ArcGIS, QGIS or GeoScence.

Preferably, the step of constructing the two-dimensional groundwater seepage equation for the study area comprises the specific steps of:

S2.1: determining the laws of physics used for neural network constraints based on the groundwater control equation, and obtaining a basic differential equation for unsteady movement of groundwater under heterogeneous isotropic conditions as follows:

$$S \frac{\partial h}{\partial t} = \frac{\partial }{\partial x} ( {K}_{x} \frac{\partial h}{\partial x} ) + \frac{\partial }{\partial y} ( {K}_{y} \frac{\partial h}{\partial y} ) + W$$

where h represents a groundwater level, S represents a water storage rate of water medium; Kₓ and K_{y} are permeability coefficients of an aquifer in x and y directions respectively; under isotropic conditions, for any point in space, a value of K is the same in all directions (Kₓ=K_{y}), but in space, a value of K will be different-heterogeneity; and W is a source-sink term, which represents an impact of external replenishment or pumping;
S2.2: the basic differential equation satisfying an initial condition of:

$$h {\vert}_{t = 0} = {h}_{0} ,$$

where h₀ represents a groundwater level at an initial time of the model; t represents a time.

Preferably, in step S3, the process of creating the deep learning neural network model integrating physical knowledge comprises the specific steps of:

S3.1: constructing a model input layer with the received groundwater level data comprising: water level height and water level position, physical parameter information comprising permeability coefficient and source-sink information, wherein the model input layer is connected to a first layer of hidden layer through a fully connected layer, if an input data is recorded as X, an output data is:

$${Z}_{1} = f ( {W}_{1} X + {b}_{1} )$$

where Z₁ represents an output of the first layer of hidden layer, W₁ represents a weight matrix of the first layer, b₁ represents a bias vector of the hidden layer of the first layer, and f represents an activation function of the network, including ReLU, Sigmoid or Tanh;

S3.2: connecting each hidden layer to a previous layer through a fully connected layer if there are more than one hidden layer, wherein an output of n-th layer of hidden layer is:

$${Z}_{n} = f ( {W}_{n} {Z}_{n - 1} + {b}_{n} )$$

where Zₙ represents the output of n-th layer of hidden layer, Wₙ represents a weight matrix of the n-th layer of hidden layer, bₙ represents a bias vector of the n-th layer of hidden layer, f represents an activation function of the network, and Zₙ₋₁ represents an input of the n-th layer hidden layer, which is also an output of (n−1)-th layer of hidden layer;

S3.3: lastly, connecting the hidden layer and the output layer through the fully connected layer, wherein the output layer is expressed as:

$${Y}_{out} = {W}_{out} \cdot {Z}_{out} + {b}_{out}$$

where Yₒᵤₜ is a prediction result of the network, Wₒᵤₜ is a weight matrix of the output layer, bₒᵤₜ is a bias vector of the output layer, and Zₒᵤₜ is an output of the last hidden layer; and

S3.4: connecting the output layer prediction results with the physical equation through the automatic differentiation technology, and using the physical equation as global constraint to guide the training process of the neural network.

Preferably, in step S4, the data error term between the PINNs model network output and the training data is calculated by the model MSE:

$${MSE}_{NN} = \frac{1}{N} {‖ Y - {Y}_{out} ‖}^{2}$$

where Y represents a true value of the groundwater level, Yₒᵤₜ represents a groundwater value predicted by the model, and N represents the sample size.

Preferably, in step S5, the process of solving the physical equation to obtain the physical residual term comprises the steps of:

S5.1: calculating a partial derivative through automatic differentiation by using a water level value h predicted by the network:

calculating a first order derivative: ∂h/∂t, ∂h/∂x and ∂h/∂y;

calculating a second order derivative:

$$\frac{{\partial }^{2} h}{\partial {x}^{2}} and \frac{{\partial }^{2} h}{\partial {y}^{2}} ;$$

S5.2: calculating a Loss Function by substituting the derivative of the network output into the physical equation to calculate the physical residual term MSE_{PDE}:

$${MSE}_{PDE} = \frac{1}{N} {‖ \frac{\partial h}{\partial t} - \frac{1}{S} ( {K}_{x} \frac{{\partial }^{2} h}{\partial {x}^{2}} - {K}_{y} \frac{{\partial }^{2} h}{\partial {y}^{2}} - W ‖}^{2}$$

where N represents a sample size.

Preferably, in step S6, the process of obtaining the overall loss of the PINNs model and backpropagating the overall loss of the PINNs back to the neural network model and processing parameter iteration to perform learning comprises the steps of:

S6.1: constructing total loss function of the PINNs network by two weighted parts: the physical residual term of the physical equation and the data error term of the neural network model:

$$MSE = {λ}_{1} {MSE}_{PDE} + {λ}_{2} {MSE}_{NN}$$

where MSE represents the total loss term of the PINNs model, λ₁ and λ₂ are weight coefficients used to balance the data error term and the physical residual, MSE_{PDE} and MSE_{NN} are the physical residual term and data error term respectively;
S6.2: calculating a gradient of the MSE loss with respect to the network output during back-propagation:

$$\frac{\partial MSE}{\partial {y}_{i}} = {λ}_{1} \frac{\partial {MSE}_{PDE}}{\partial {y}_{i}} + {λ}_{2} ( - \frac{2}{N} ( {Y}_{i} - {y}_{i} ) )$$

where MSE represents the total loss term of the PINNs model, λ₁ and λ₂ are weight coefficients, MSE_{PDE} and MSE_{NN} are the physical residual term and data error term respectively, N represents the sample size, Yᵢ represents the actual groundwater level value, and yᵢ represents the groundwater level value predicted by the model;
S6.3: using the calculated gradient, updating the weights in the network through an optimization algorithm, and continuously processing iterated training until the model loss function converges, wherein the optimization algorithm is SGD or Adam.

Compared with the existing technologies, the present invention provides a new simulation method for characterizing the temporal and spatial evolution of groundwater level, which has the following beneficial effects:

The present invention obtains regional precipitation information based on remote sensing image data; and further obtains long-term groundwater level data based on long-term groundwater monitoring wells. Based on the groundwater level information, a variety of hydrogeological parameter information is superimposed, and the two-dimensional groundwater seepage equation is used as the physical mechanism to construct a regional neural network model with a physical mechanism, thereby simulating the temporal and spatial evolution of the regional groundwater level with high efficiency, hence providing a scientific basis for protecting the safety of regional groundwater and promoting the sustainable development of groundwater resources.

### BRIEF DESCRIPTION OF THE DRAWINGS

FIG. 1 is a schematic diagram of a new simulation method for characterizing the spatiotemporal changes of groundwater level according to a preferred embodiment of the present invention.

FIG. 2 illustrates a network structure of a new neural network model for simulating the spatiotemporal changes of groundwater level according to the preferred embodiment of the present invention.

FIG. 3 illustrates a schematic diagram showing the contribution of each characteristic factor to the network according to the preferred embodiment of the present invention.

### DETAILED DESCRIPTION OF THE PREFERRED EMBODIMENT

The following detailed description of the preferred embodiment is the preferred mode of carrying out the invention. The description is not to be taken in any limiting sense. It is presented for the purpose of illustrating the general principles of the present invention.

Unless otherwise specified, the terms used have the common meanings understood by those skilled in the art.

Groundwater, which is one of the most important freshwater resources on Earth, not only affects the ecological environment, but also controls the development of social economy. Traditional groundwater simulation methods mainly rely on numerical solutions, such as the finite element method (FEM), the finite difference method (FDM) and the finite volume method (FVM). These methods require explicitly discretizing the equations and building networks based on the geometry and boundary conditions of the problem. For complex geometries or multi-physics coupled problems, modeling and solving can be complex and time-consuming. In addition, these types of method show obvious limitations in dealing with nonlinear problems. In order to solve the above problems, the present invention provides a simulation method to characterize the spatiotemporal change of groundwater level.

PINNs is a neural network framework that incorporates physical knowledge into deep learning. The core idea of PINNs is to embed laws of physics into the loss function of the neural network, so that the model can not only fit the data, but also guide the training process through the constraints of the physical process, thereby enhancing the interpretability of the model. The model's predictions can be explained by physical laws, thus reducing the “black box” nature of the neural network. Because the embedded physical mechanism is universal, PINNs can demonstrate better generalization capabilities when dealing with unseen physical scenarios or conditions. Despite the success of PINNs in many fields, their application in groundwater simulation is still relatively limited. The present invention generalizes the groundwater flow in the study area into a two-dimensional unsteady flow problem, integrates data including the groundwater water level over time, water level geological parameters and precipitation data, and through taking the basic differential equations of groundwater unsteady motion as neural network constraints, explores the potential of PINNs in groundwater level simulation and prediction, and provides a new method for accurate and efficient groundwater simulation. Specifically, the simulation method includes the following features:

### Embodiment 1

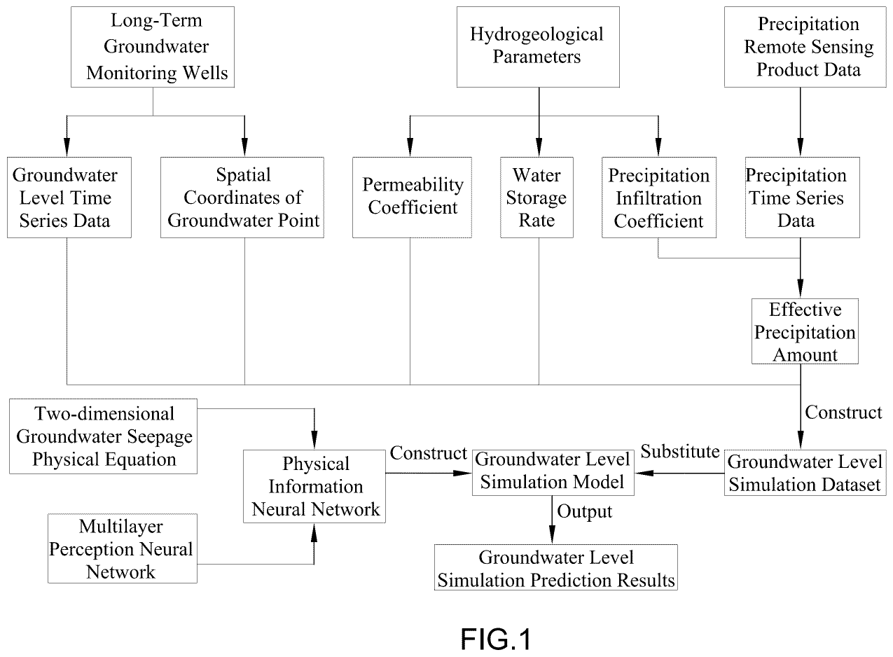

Referring to FIG. 1 of the drawings, a new type of simulation method for characterizing the temporal and spatial changes of groundwater level, executed by a computer or processor, comprises the following steps:

S1: Through a long-term time series satellite remote sensing precipitation product (product that measure and estimate precipitation on Earth using satellite observation technology), obtain monthly precipitation data covering a study area (such as ERA5-Land data). Through long-term groundwater monitoring wells within the study area, obtain monthly groundwater level data. In other words, the monthly precipitation data covering the study area and the monthly groundwater level data are obtained and input into the computer.

When acquiring remote sensing image data, geoscientific related software is required for processing. The geoscientific related processing software is ArcGIS, QGIS, or GeoScence.

S2: Obtain basic hydrogeological data within the study area, combine the basic hydrogeological data with a groundwater control equation, and construct a two-dimensional groundwater seepage equation for the study area. The groundwater control equation is a combination of Darcy's law an equation of continuity to describe the flow of groundwater in porous media.

S2.1: Relying on the groundwater control equation, the laws of physics used for the neural network constraints are determined. Under heterogeneous isotropic conditions, the basic differential equation for the unsteady movement of groundwater may be expressed as follows:

$$S \frac{\partial h}{\partial t} = \frac{\partial }{\partial x} ( {K}_{x} \frac{\partial h}{\partial x} ) + \frac{\partial }{\partial y} ( {K}_{y} \frac{\partial h}{\partial y} ) + W$$

where h represents the groundwater level, S represents the water storage rate of the water medium; Kₓ and K_{y} are the permeability coefficients of the aquifer in the x and y directions respectively; ∂ represents the partial derivative, t represents the time, x and y are spatial coordinates; under isotropic conditions, for any point in space, the value of K is the same in all directions (Kₓ=K_{y}), but in space, the value of K will be different-heterogeneity; and W is the source-sink term, which represents the impact of external replenishment or pumping.

S2.2: The basic differential equation for the unsteady movement of groundwater satisfies an initial condition: h|ₜ₌₀=h₀, where h₀ represents the groundwater level at an initial time of the model; t represents the time.

S3: Based on a two-dimensional groundwater seepage equation of the study area and combined with a neural network model, construct a deep learning neural network model integrating physical knowledge, namely the PINNs model.

S3.1: Construct the model input layer with the received groundwater level information including water level height, water level position and the physical parameter information including the permeability coefficient and the source-sink information. The input layer is connected to the first layer of hidden layer through a fully connected layer. If the input data is recorded as X, the output data is:

$${Z}_{1} = f ( {W}_{1} X + {b}_{1} )$$

where Z₁ represents the output of the first hidden layer, W₁ represents the weight matrix of the first layer, X represents the input layer data of time neural network (that is the input data composed of t, x, y, K, and K_{y}), b₁ represents the bias vector of the first hidden layer, and f represents the activation function of the network of which common activation functions include ReLU, Sigmoid and Tanh.

It is worth mentioning that one or more activation functions may be selected based on the specific layer requirements. According to this embodiment, one activation function is used.

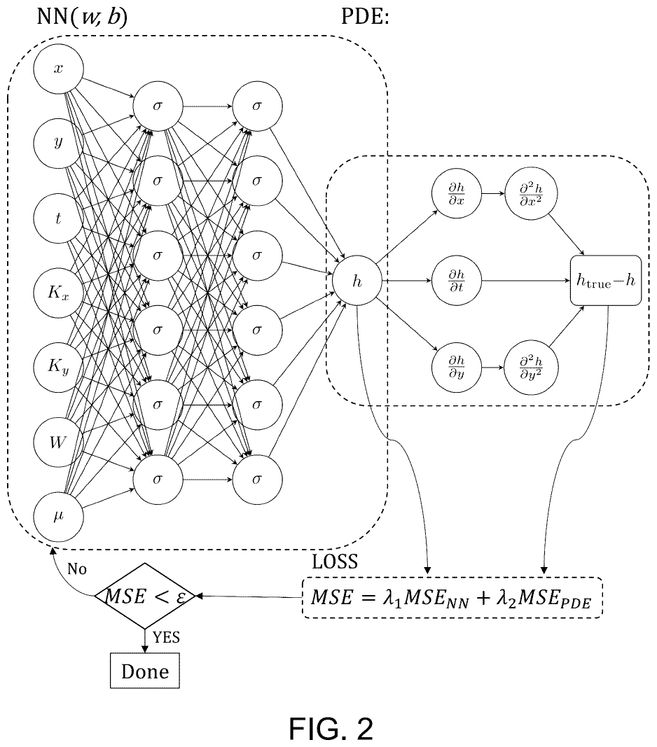

As shown in FIG. 2 of the drawings, x, y, t, Kₓ, K_{y} neurons (the leftmost column) are the model input layer of the network, which are groundwater level information and physical parameter information, hₜᵣᵤₑ is the actual groundwater level, ε is the convergence condition.

S3.2: When there are multiple hidden layers, each hidden layer is connected to the previous layer through a fully connected layer:

$${Z}_{n} = f ( {W}_{n} {Z}_{n - 1} + {b}_{n} )$$

where Zₙ represents the output of the n-th layer of hidden layer, Wₙ represents the weight matrix of the n-th layer of hidden layer, bₙ represents the bias vector of the n-th layer of hidden layer, f represents the activation function of the network, and Zₙ₋₁ represents the input of the n-th layer of hidden layer, which is also the output of the (n−1)-th layer of hidden layer.

S3.3: Finally, the hidden layer and the output layer are also connected through a fully connected layer. The output layer can be expressed as:

$${Y}_{out} = {W}_{out} \cdot {Z}_{out} + {b}_{out}$$

Where Yₒᵤₜ is the prediction result of the network, Wₒᵤₜ is the weight matrix of the output layer, bₒᵤₜ is the bias vector of the output layer, and Zₒᵤₜ is the output of the last hidden layer.

S3.4: Through automatic differentiation technology, the output layer prediction results generated from the output layer are connected with the physical equation (that is the two-dimensional groundwater seepage equation for the study area), and the physical equation is used as global constraint to guide the training process of the neural network.

Preferably, the data error term between the PINNs model network output and the training data in step S4 is calculated by the model MSE:

$${MSE}_{NN} = \frac{1}{N} {‖ Y - {Y}_{out} ‖}^{2}$$

where Y represents the true value of the groundwater level, Yₒᵤₜ represents the groundwater value predicted by the model, and N represents the sample size.

S4: The precipitation data and groundwater level data obtained in S1 are used as input to train the deep learning neural network model integrating physical knowledge-PINNs model, and the data error term between the network output and the training data is obtained.

The training results are the network output results, which are also the network prediction results.

The data error term between the PINNs model network output and the training data in S4 is calculated by the model MSE.

$${MSE}_{NN} = \frac{1}{N} {‖ Y - {Y}_{out} ‖}^{2}$$

where Y represents the true value of the groundwater level, Yₒᵤₜ represents the groundwater value predicted by the model, and N represents the sample size.

S5: Substitute the network output results obtained from the model in step S4 into the physical equation, solve the physical equation through automatic differentiation, and obtain the physical residual term.

S5.1: Using the water level value h predicted by the network (which is the network prediction result obtained in step S4), the partial derivatives are calculated by automatic differentiation:

Calculate the first order derivative: ∂h/∂t, ∂h/∂x and ∂h/∂y.

Calculate the second order derivative:

$$\frac{{\partial }^{2} h}{\partial {x}^{2}} and \frac{{\partial }^{2} h}{\partial {y}^{2}} .$$

S5.2: Calculate the Loss Function:

Substitute the derivative of the network output into the physical equation to calculate:

$${MSE}_{PDE} = \frac{1}{N} {‖ \frac{\partial h}{\partial t} - \frac{1}{S} ( {K}_{x} \frac{{\partial }^{2} h}{\partial {x}^{2}} - {K}_{y} \frac{{\partial }^{2} h}{\partial {y}^{2}} - W ‖}^{2}$$

where N represents the sample size.

S6: The data error term obtained by step S4 is superimposed with the physical residual term obtained by step S5 to obtain the overall loss of the PINNs model, which is back-propagated back to the neural network model. Through model iteration, learning is performed to achieve accurate simulation of groundwater level.

S6.1: The total loss function of the PINNs network is constructed by the physical residual term of the physical equation and the data error term of the neural network model, which are weighted.

$$M S E = {λ}_{1} M S {E}_{P D E} + {λ}_{2} M S {E}_{N N}$$

where MSE represents the total loss term of the PINNs model, λ₁ and λ₂ are weight coefficients used to balance the data error term and the physical residual, MSE_{PDE} and MSE_{NN} are the physical residual term and data error term respectively.

S6.2: During back-propagation, the gradient of the MSE loss with respect to the network output is calculated:

$$\frac{\partial M S E}{\partial {y}_{i}} = {λ}_{1} \frac{\partial M S {E}_{P D E}}{\partial {y}_{i}} + {λ}_{2} ( - \frac{2}{N} ( {Y}_{i} - {y}_{i} ) )$$

where MSE represents the total loss term of the PINNs model, λ₁ and λ₂ are weight coefficients, MSE_{PDE} and MSE_{NN} are the physical residual term and data error term respectively, N represents the sample size, Yᵢ represents the actual groundwater level value, and yᵢ represents the groundwater level value predicted by the model.

S6.3: Using the calculated gradient, the weights in the network are updated through an optimization algorithm, and training is iterated continuously until the model loss function converges; wherein the optimization algorithm is SGD or Adam.

In other words, the training of the neural network is determined to be complete when the Loss value is smaller than a preset & value.

### Embodiment 2

This embodiment is different from Embodiments 1 in that: through the ERA5-Land remote sensing images on the GEE platform, monthly precipitation data from 1984 to 2023 are obtained. The study area is Linyi City, Shandong Province. The water levels of existing long-term groundwater monitoring wells (a total of 11 groundwater monitoring wells distributed within the study area) are obtained, their temporal patterns over time are analyzed, and simulations are performed. The method includes mainly the following steps:

### Step (1):

Through long-term satellite remote sensing precipitation outputs, monthly precipitation data with a resolution of 0.1° covering the study area are obtained; combined with long-term groundwater observation wells within the study area, monthly groundwater level information is obtained.

### Step (2):

The basic hydrogeological data within the study area are obtained and combined with the groundwater control equation to construct a two-dimensional groundwater seepage equation for the study area.

The permeability coefficient describes the water permeability of underground media and directly affects the flow velocity and flow distribution of groundwater. The water storage rate describes the ability to release or store water volume from a column with a unit horizontal area and height equal to the thickness of the aquifer when the water head of the aquifer drops or rises by a unit height.

### Step (3):

Based on the two-dimensional groundwater seepage equation in the study area, combined with the neural network model, a deep learning neural network model integrating physical knowledge—PINNs model is constructed.

Specifically, the neural network is multilayered Perception (MLP) neural network model.

### Step (4):

Input data, train the deep learning neural network model that integrates physical knowledge, and obtain the data error term between the network output and the training data

### Step (5):

The network output results obtained by the model are substituted into the physical equation, and the physical equation is solved by automatic differentiation to obtain the physical residual term.

### Step (6):

Superimpose the data error term of the neural network with the physical residual term in the process of solving the physical equation to obtain the overall loss term of the PINNs model, and back-propagate it back to the neural network model. Through model iteration, learning is carried out to achieve accurate simulation of groundwater level.

### Step (7):

The constructed groundwater level simulation model, that is the PINNs model, is explained using SHAP to obtain the importance of each characteristic factor in the PINNs network.

The model simulation results show that the PINNs model score is 0.87 and the RMSE is 1.98 m. The results show that the model has a good fit and high accuracy in groundwater level simulation.

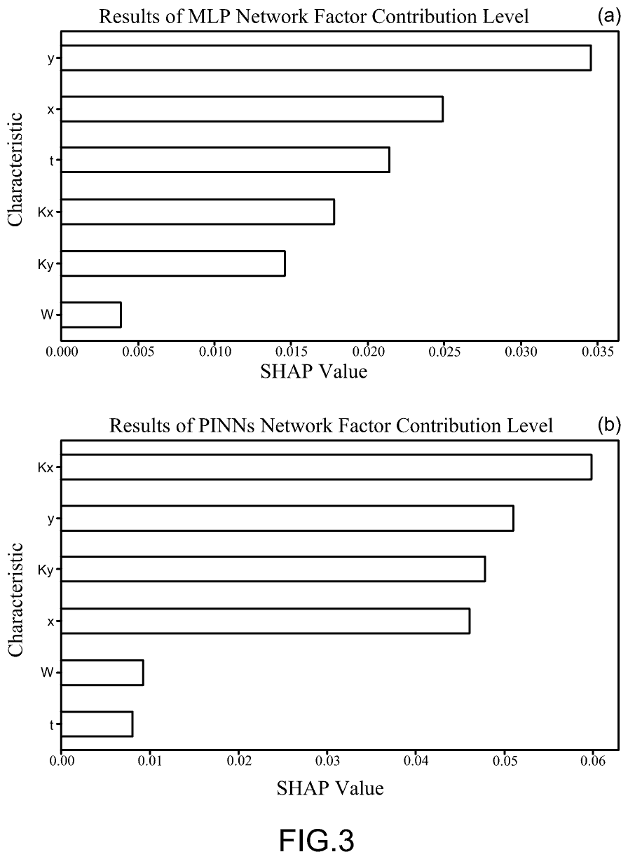

As shown in FIG. 3, in the PINNs network, the contribution of the permeability coefficients Kₓ and K_{y} to the network is significantly higher than that of the traditional MLP network, followed by the spatial position. This shows that for the PINNs network, the model prediction focuses more on the physical process than the spatial position, which enhances the interpretability of the model prediction results.

One skilled in the art will understand that the embodiment of the present invention as shown in the drawings and described above is exemplary only and not intended to be limiting.

It will thus be seen that the objects of the present invention have been fully and effectively accomplished. It embodiments have been shown and described for the purposes of illustrating the functional and structural principles of the present invention and is subject to change without departure from such principles. Therefore, this invention includes all modifications encompassed within the spirit and scope of the following claims.

1. A simulation method to characterize the spatiotemporal change of groundwater level, characterized in that, the method, executed by a processor, comprises the steps of:
S1: obtaining monthly precipitation data covering a study area through long-term satellite remote sensing precipitation product; obtaining monthly groundwater level data through long-term groundwater monitoring wells within the study area;
S2: obtaining basic hydrogeological data within the study area, combining the basic hydrogeological data with a groundwater control equation, and constructing a two-dimensional groundwater seepage equation for the study area;
S3: creating a deep learning neural network model integrating physical knowledge, namely the PINNs model, based on the two-dimensional groundwater seepage equation of the study area combined with a neural network model;
S4: training the deep learning neural network model integrating physical knowledge—the PINNs model by using the precipitation data and groundwater level data obtained in step S1, thereby obtaining a data error term between network output and the training data;
S5: substituting the network output results obtained from the model in step S4 into a physical equation, solving the physical equation through automatic differentiation, and obtaining a physical residual term;
S6: superimposing the data error term obtained from step S4 with the physical residual term obtained by step S5 to obtain an overall loss of the PINNs model, then processing back-propagation to propagate the overall loss of the PINNs model back to the neural network model, thereby learning is performed through model iteration processing to achieve accurate simulation of groundwater level.

2. The simulation method to characterize the spatiotemporal change of groundwater level according to claim 1, when obtaining the monthly precipitation data covering the study area through the long-term satellite remote sensing precipitation product in step S1, a geoscientific related software is employed for data processing, wherein the geoscientific related software is selected from the group consisting of: ArcGIS, QGIS, and GeoScence.

3. The simulation method to characterize the spatiotemporal change of groundwater level according to claim 1, wherein the step of constructing the two-dimensional groundwater seepage equation for the study area comprises the sub-steps of:
S2.1: determining the laws of physics used for neural network constraints based on the groundwater control equation, and obtaining a basic differential equation for unsteady movement of groundwater under heterogeneous isotropic conditions as follows:
$$S \frac{\partial h}{\partial t} = \frac{\partial }{\partial x} ( {K}_{x} \frac{\partial h}{\partial x} ) + \frac{\partial }{\partial y} ( {K}_{y} \frac{\partial h}{\partial y} ) + W$$
where h represents a groundwater level, S represents a specific storage of an aquifer; Kₓ and K_{y} are hydraulic conductivity of the aquifer in X and y directions respectively; under isotropic conditions, for any point in space, a value of K is the same in all directions (Kₓ=K_{y}), but in space, a value of K will be different-heterogeneity; and W is a source-sink term, which represents an impact of external replenishment or pumping;
S2.2: the basic differential equation satisfying an initial condition of:
$$h {\vert}_{t = 0} = {h}_{0} ,$$
where h₀ represents a groundwater level at an initial time of the model; t represents a time.

4. The simulation method to characterize the spatiotemporal change of groundwater level according to claim 1, wherein the step of creating the deep learning neural network model integrating physical knowledge in step S3 comprises the sub-steps of:
S3.1: constructing a model input layer with the received groundwater level data comprising: water level height and water level position, physical parameter information comprising hydraulic conductivity and source-sink information, wherein the model input layer is connected to a first layer of hidden layer through a fully connected layer, if an input data is recorded as X, an output data is:
$${Z}_{1} = f ( {W}_{1} X + {b}_{1} )$$
where Z₁ represents an output of the first layer of hidden layer, W₁ represents a weight matrix of the first layer, b₁ represents a bias vector of the hidden layer of the first layer, and f represents an activation function of the network, including ReLU, Sigmoid or Tanh;
S3.2: connecting each hidden layer to a previous layer through a fully connected layer if there are more than one hidden layer, wherein an output of n-th layer of hidden layer is:
$${Z}_{n} = f ( {W}_{n} {Z}_{n - 1} + {b}_{n} )$$
where Zₙ represents the output of n-th layer of hidden layer, Wₙ represents a weight matrix of the n-th layer of hidden layer, bₙ represents a bias vector of the n-th layer of hidden layer, f represents an activation function of the network, and Zₙ₋₁ represents an input of the n-th layer hidden layer, which is also an output of (n−1)-th layer of hidden layer;
S3.3: lastly, connecting the hidden layer and the output layer through the fully connected layer, wherein the output layer is expressed as:
$${Y}_{o u t} = {W}_{o u t} \cdot {Z}_{o u t} + {b}_{o u t}$$
where Yₒᵤₜ is a prediction result of the network, Wₒᵤₜ is a weight matrix of the output layer, bₒᵤₜ is a bias vector of the output layer, and Zₒᵤₜ is an output of the last hidden layer; and
S3.4: connecting the output layer prediction results with the physical equation through the automatic differentiation technology, and using the physical equation as global constraint to guide the training process of the neural network.

5. The simulation method to characterize the spatiotemporal change of groundwater level according to claim 1, wherein the data error term MSE_{NN} between the PINNs model network output and the training data in step S4 is calculated by the model MSE:
$$M S {E}_{N N} = \frac{1}{N} {‖ Y - {Y}_{o u t} ‖}^{2}$$
where Y represents a true value of the groundwater level, Yₒᵤₜ represents a groundwater value predicted by the model, and N represents the sample size.

6. The simulation method to characterize the spatiotemporal change of groundwater level according to claim 5, wherein in step S5, the process of solving the physical equation to obtain the physical residual term comprises the steps of:
S5.1: calculating a partial derivative through automatic differentiation by using a water level value h predicted by the network:
calculating a first order derivative: ∂h/∂t, ∂h/∂x and ∂h/∂y;
calculating a second order derivative:
$$\frac{\partial }{\partial x} ( {K}_{x} \frac{\partial h}{\partial x} ) \underline{and} \frac{\partial }{\partial y} ( {K}_{y} \frac{\partial h}{\partial y} ) .$$
S5.2: calculating a Loss Function by substituting the derivative of the network output into the physical equation to calculate the physical residual term MSE_{PDE}:
$${MSE}_{PDE} = \frac{1}{N} {‖ \frac{\partial h}{\partial t} - \frac{1}{S} [ \frac{\partial }{\partial x} ( {K}_{x} \frac{\partial h}{\partial x} ) + \frac{\partial }{\partial y} ( {K}_{y} \frac{\partial h}{\partial y} ) + W ] ‖}^{2}$$
where N represents a sample size.

7. The simulation method to characterize the spatiotemporal change of groundwater level according to claim 6, wherein in step S6, the process of obtaining the overall loss of the PINNs model and backpropagating the overall loss of the PINNs back to the neural network model and processing parameter iteration to perform learning comprises the steps of:
S6.1: constructing total loss function of the PINNs network by two weighted parts: the physical residual term of the physical equation and the data error term of the neural network model:
$$M S E = {λ}_{1} M S {E}_{P D E} + {λ}_{2} M S {E}_{N N}$$
where MSE represents the total loss term of the PINNs model, λ₁ and λ₂ are weight coefficients used to balance the data error term and the physical residual, MSE_{PDE} and MSE_{NN} are the physical residual term and data error term respectively;
S6.2: calculating a gradient of the MSE loss with respect to the network output during back-propagation:
$$\frac{\partial M S E}{\partial {y}_{i}} = {λ}_{1} \frac{\partial M S {E}_{P D E}}{\partial {y}_{i}} + {λ}_{2} ( - \frac{2}{N} ( {Y}_{i} - {y}_{i} ) )$$
where MSE represents the total loss term of the PINNs model, λ₁ and λ₂ are weight coefficients, MSE_{PDE} and MSE_{NN} are the physical residual term and data error term respectively, N represents the sample size, Yᵢ represents the actual groundwater level value, and yᵢ represents the groundwater level value predicted by the model;
S6.3: using the calculated gradient, updating the weights in the network through an optimization algorithm, and continuously processing iterated training until the model loss function converges, wherein the optimization algorithm is SGD or Adam.

8. The simulation method to characterize the spatiotemporal change of groundwater level according to claim 2, the calculation is processed by Python or Matlab calculation.

9. The simulation method to characterize the spatiotemporal change of groundwater level according to claim 3, the calculation is processed by Python or Matlab calculation.

10. The simulation method to characterize the spatiotemporal change of groundwater level according to claim 4, the calculation is processed by Python or Matlab calculation.

11. The simulation method to characterize the spatiotemporal change of groundwater level according to claim 5, the calculation is processed by Python or Matlab calculation.

12. The simulation method to characterize the spatiotemporal change of groundwater level according to claim 6, the calculation is processed by Python or Matlab calculation.

13. The simulation method to characterize the spatiotemporal change of groundwater level according to claim 2, wherein the step of constructing the two-dimensional groundwater seepage equation for the study area comprises the sub-steps of:
S2.1: determining the laws of physics used for neural network constraints based on the groundwater control equation, and obtaining a basic differential equation for unsteady movement of groundwater under heterogeneous isotropic conditions as follows:
$$S \frac{\partial h}{\partial t} = \frac{\partial }{\partial x} ( {K}_{x} \frac{\partial h}{\partial x} ) + \frac{\partial }{\partial y} ( {K}_{y} \frac{\partial h}{\partial y} ) + W$$
where h represents a groundwater level, S represents a specific storage of an aquifer; Kₓ and K_{y} are hydraulic conductivity of the aquifer in X and y directions respectively; under isotropic conditions, for any point in space, a value of K is the same in all directions (Kₓ=K_{y}), but in space, a value of K will be different-heterogeneity; and W is a source-sink term, which represents an impact of external replenishment or pumping;
S2.2: the basic differential equation satisfying an initial condition of:
$$h {\vert}_{t = 0} = {h}_{0} ,$$
where h₀ represents a groundwater level at an initial time of the model; t represents a time.

14. The simulation method to characterize the spatiotemporal change of groundwater level according to claim 13, wherein the step of creating the deep learning neural network model integrating physical knowledge comprises the sub-steps of:
S3.1: constructing a model input layer with the received groundwater level data comprising: water level height and water level position, physical parameter information comprising hydraulic conductivity and source-sink information, wherein the model input layer is connected to a first layer of hidden layer through a fully connected layer, if an input data is recorded as X, an output data is:
$${Z}_{1} = f ( {W}_{1} X + {b}_{1} )$$
where Z₁ represents an output of the first layer of hidden layer, W₁ represents a weight matrix of the first layer, b₁ represents a bias vector of the hidden layer of the first layer, and f represents an activation function of the network, including ReLU, Sigmoid or Tanh;
S3.2: connecting each hidden layer to a previous layer through a fully connected layer if there are more than one hidden layer, wherein an output of n-th layer of hidden layer is:
$${Z}_{n} = f ( {W}_{n} {Z}_{n - 1} + {b}_{n )}$$
where Zₙ represents the output of n-th layer of hidden layer, Wₙ represents a weight matrix of the n-th layer of hidden layer, bₙ represents a bias vector of the n-th layer of hidden layer, f represents an activation function of the network, and Zₙ₋₁ represents an input of the n-th layer hidden layer, which is also an output of (n−1)-th layer of hidden layer;
S3.3: lastly, connecting the hidden layer and the output layer through the fully connected layer, wherein the output layer is expressed as:
$${Y}_{out} = {W}_{out} \cdot {Z}_{out} + {b}_{out}$$
where Yₒᵤₜ is a prediction result of the network, Wₒᵤₜ is a weight matrix of the output layer, bₒᵤₜ is a bias vector of the output layer, and Zₒᵤₜ is an output of the last hidden layer; and
S3.4: connecting the output layer prediction results with the physical equation through the automatic differentiation technology, and using the physical equation as global constraint to guide the training process of the neural network.

15. The simulation method to characterize the spatiotemporal change of groundwater level according to claim 14, wherein the data error term MSE_{NN} between the PINNs model network output and the training data in step S4 is calculated by the model MSE:
$${MSE}_{NN} = \frac{1}{N} {‖ Y - {Y}_{out} ‖}^{2}$$
where Y represents a true value of the groundwater level, Yₒᵤₜ represents a groundwater value predicted by the model, and N represents the sample size.

16. The simulation method to characterize the spatiotemporal change of groundwater level according to claim 15, wherein in step S5, the process of solving the physical equation to obtain the physical residual term comprises the steps of:
S5.1: calculating a partial derivative through automatic differentiation by using a water level value h predicted by the network:
calculating a first order derivative: ∂h/∂t, ∂h/∂x and ∂h/∂y;
calculating a second order derivative:
$$\frac{\partial }{\partial x} ( {K}_{x} \frac{\partial h}{\partial x} ) and \frac{\partial }{\partial y} ( {K}_{y} \frac{\partial h}{\partial y} ) ;$$
S5.2: calculating a Loss Function by substituting the derivative of the network output into the physical equation to calculate the physical residual term MSE_{PDE}:
$${MSE}_{PDE} = \frac{1}{N} {‖ \frac{\partial h}{\partial t} - \frac{1}{S} [ \frac{\partial }{\partial x} ( {K}_{x} \frac{\partial h}{\partial x} ) + \frac{\partial }{\partial y} ( {K}_{y} \frac{\partial h}{\partial y} ) + W ] ‖}^{2}$$
where N represents a sample size.

17. The simulation method to characterize the spatiotemporal change of groundwater level according to claim 16, wherein in step S6, the process of obtaining the overall loss of the PINNs model and backpropagating the overall loss of the PINNs back to the neural network model and processing parameter iteration to perform learning comprises the steps of:
S6.1: constructing total loss function of the PINNs network by two weighted parts: the physical residual term of the physical equation and the data error term of the neural network model:
$$MSE = {λ}_{1} {MSE}_{PDE} + {λ}_{2} {MSE}_{NN}$$
where MSE represents the total loss term of the PINNs model, λ₁ and λ₂ are weight coefficients used to balance the data error term and the physical residual, MSE_{PDE} and MSE_{NN} are the physical residual term and data error term respectively;
S6.2: calculating a gradient of the MSE loss with respect to the network output during back-propagation:
$$\frac{\partial MSE}{\partial {y}_{i}} = {λ}_{1} \frac{\partial {MSE}_{PDE}}{\partial {y}_{i}} + {λ}_{2} ( - \frac{2}{N} ( {Y}_{i} - {y}_{i} ) )$$
where MSE represents the total loss term of the PINNs model, λ₁ and λ₂ are weight coefficients, MSE_{PDE} and MSE_{NN} are the physical residual term and data error term respectively, N represents the sample size, Yᵢ represents the actual groundwater level value, and yᵢ represents the groundwater level value predicted by the model;
S6.3: using the calculated gradient, updating the weights in the network through an optimization algorithm, and continuously processing iterated training until the model loss function converges, wherein the optimization algorithm is SGD or Adam.

18. The simulation method to characterize the spatiotemporal change of groundwater level according to 17, the calculation is processed by Python or Matlab calculation.

19. The simulation method to characterize the spatiotemporal change of groundwater level according to claim 3, wherein the step of creating the deep learning neural network model integrating physical knowledge comprises the sub-steps of:
S3.1: constructing a model input layer with the received groundwater level data comprising: water level height and water level position, physical parameter information comprising hydraulic conductivity and source-sink information, wherein the model input layer is connected to a first layer of hidden layer through a fully connected layer, if an input data is recorded as X, an output data is:
$${Z}_{1} = f ( {W}_{1} X + {b}_{1} )$$
where Z₁ represents an output of the first layer of hidden layer, W₁ represents a weight matrix of the first layer, b₁ represents a bias vector of the hidden layer of the first layer, and f represents an activation function of the network, including ReLU, Sigmoid or Tanh;
S3.2: connecting each hidden layer to a previous layer through a fully connected layer if there are more than one hidden layer, wherein an output of n-th layer of hidden layer is:
$${Z}_{n} = f ( {W}_{n} {Z}_{n - 1} + {b}_{n} )$$
where Zₙ represents the output of n-th layer of hidden layer, Wₙ represents a weight matrix of the n-th layer of hidden layer, bₙ represents a bias vector of the n-th layer of hidden layer, f represents an activation function of the network, and Zₙ₋₁ represents an input of the n-th layer hidden layer, which is also an output of (n−1)-th layer of hidden layer;
S3.3: lastly, connecting the hidden layer and the output layer through the fully connected layer, wherein the output layer is expressed as:
$${Y}_{out} = {W}_{out} \cdot {Z}_{out} + {b}_{out}$$
where Yₒᵤₜ is a prediction result of the network, Wₒᵤₜ is a weight matrix of the output layer, bₒᵤₜ is a bias vector of the output layer, and Zₒᵤₜ is an output of the last hidden layer; and
S3.4: connecting the output layer prediction results with the physical equation through the automatic differentiation technology, and using the physical equation as global constraint to guide the training process of the neural network,
wherein the data error term MSE_{NN} between the PINNs model network output and the training data in step S4 is calculated by the model MSE:
$${MSE}_{NN} = \frac{1}{N} {‖ Y - {Y}_{out} ‖}^{2}$$
where Y represents a true value of the groundwater level, Yₒᵤₜ represents a groundwater value predicted by the model, and N represents the sample size.

20. The simulation method to characterize the spatiotemporal change of groundwater level according to claim 19, wherein in step S5, the process of solving the physical equation to obtain the physical residual term comprises the steps of:
S5.1: calculating a partial derivative through automatic differentiation by using a water level value h predicted by the network:
calculating a first order derivative: ∂h/∂t, ∂h/∂x and ∂h/∂y;
calculating a second order derivative:
$$\frac{\partial }{\partial x} ( {K}_{x} \frac{\partial h}{\partial x} ) and \frac{\partial }{\partial y} ( {K}_{y} \frac{\partial h}{\partial y} ) ;$$
S5.2: calculating a Loss Function by substituting the derivative of the network output into the physical equation to calculate the physical residual term MSE_{PDE}:
$${MSE}_{PDE} = \frac{1}{N} {‖ \frac{\partial h}{\partial t} - \frac{1}{S} [ \frac{\partial }{\partial x} ( {K}_{x} \frac{\partial h}{\partial x} ) + \frac{\partial }{\partial y} ( {K}_{y} \frac{\partial h}{\partial y} ) + W ] ‖}^{2}$$
where N represents a sample size,
wherein in step S6, the process of obtaining the overall loss of the PINNs model and backpropagating the overall loss of the PINNs back to the neural network model and processing parameter iteration to perform learning comprises the steps of:
S6.1: constructing total loss function of the PINNs network by two weighted parts: the physical residual term of the physical equation and the data error term of the neural network model:
$$MSE = {λ}_{1} {MSE}_{PDE} + {λ}_{2} {MSE}_{NN}$$
where MSE represents the total loss term of the PINNs model, λ₁ and λ₂ are weight coefficients used to balance the data error term and the physical residual, MSE_{PDE} and MSE_{NN} are the physical residual term and data error term respectively;
S6.2: calculating a gradient of the MSE loss with respect to the network output during back-propagation:
$$\frac{\partial MSE}{\partial {y}_{i}} = {λ}_{1} \frac{\partial {MSE}_{PDE}}{\partial {y}_{i}} + {λ}_{2} ( - \frac{2}{N} ( {Y}_{i} - {y}_{i} ) )$$
where MSE represents the total loss term of the PINNs model, λ₁ and λ₂ are weight coefficients, MSE_{PDE} and MSE_{NN} are the physical residual term and data error term respectively, N represents the sample size, Yᵢ represents the actual groundwater level value, and yᵢ represents the groundwater level value predicted by the model; and
S6.3: using the calculated gradient, updating the weights in the network through an optimization algorithm, and continuously processing iterated training until the model loss function converges, wherein the optimization algorithm is SGD or Adam.
